(19) United States
(12) Patent Application Publication
(10) Pub. No.: US 2025/0389781 A1
(43) Pub. Date: Dec. 25, 2025

(54) BATTERY ASSEMBLY AND MONITORING METHOD OF THE SAME

(71) Applicant: SK On Co., Ltd., Seoul (KR)

(72) Inventor: Soo Bin LEE, Daejeon (KR)

(21) Appl. No.: 19/234,276

(22) Filed: Jun. 11, 2025

(30) Foreign Application Priority Data
Jun. 20, 2024 (KR) 10-2024-0080361

(51) Int. Cl. G01R 31/389; G01R 31/385; G01R 31/392; H01M 10/42; H01M 10/48; H01M 50/119; H01M 50/503; H01M 50/507

(52) U.S. Cl. CPC G01R 31/389; G01R 31/385; G01R 31/392; H01M 10/4257; H01M 10/482; H01M 50/119; H01M 50/503; H01M 50/507

(57) ABSTRACT

The present disclosure relates to a battery assembly and a monitoring method thereof. A battery assembly in one implementation of the present disclosure includes a plurality of battery cells each including an electrode assembly, an exterior material accommodating the electrode assembly therein, and an electrode lead connected to the electrode assembly and protruding to an outside of the exterior material, a busbar electrically connected to the electrode lead of each of the plurality of battery cells, a through hole formed through the busbar, a measurement part measuring electrical characteristics of at least one battery cell among the plurality of battery cells, and an insulation measuring member, one end of which is connected to the exterior material of one of the plurality of battery cells and an other end of which is electrically connected to the measurement part.

### CROSS-REFERENCE TO RELATED PATENT APPLICATION

The present application claims priority under 35 U.S.C. § 119 (a) to Korean patent application number 10-2024-0080361 filed on Jun. 20, 2024 in the Korean Intellectual Property Office, the entire disclosure of which is incorporated by reference herein.

### BACKGROUND OF THE INVENTION

### 1. Field

The present disclosure relates to a battery assembly and a monitoring method thereof. More specifically, the present disclosure relates to a battery assembly having improved safety by quickly and accurately determining whether respective cells constituting the battery assembly are deteriorated, and a method of monitoring the battery assembly.

### 2. Description of the Related Art

A secondary battery converts electrical energy into chemical energy and stores the chemical energy so that the secondary battery can be reused multiple times through charging and discharging. In order to obtain desired output and performance, a plurality of secondary batteries may be grouped and manufactured into a battery assembly.

Each of the secondary batteries in the battery assembly generally has a surface made of an insulating exterior material to protect an electrode assembly embedded therein from external impacts. However, when deterioration occurs in the exterior material due to external or internal factors, internal short-circuits may be caused, and as a result, fatal safety problems such as thermal runaway may occur.

### SUMMARY OF THE INVENTION

An aspect of the present disclosure is to provide a battery assembly with improved safety.

Another aspect of the present disclosure is to provide a method of monitoring a battery assembly capable of quickly and accurately determining whether each battery cell in the battery assembly is degraded.

Meanwhile, the present disclosure may be widely applied in the fields of electric vehicles, battery charging stations, energy storage systems (ESS), and other green technologies such as photovoltaics and wind power using batteries. In addition, the present disclosure may be used in eco-friendly mobility, including electric vehicles and hybrid vehicles, to prevent climate change by suppressing air pollution and greenhouse fluid emissions.

A battery assembly according to embodiments of the present disclosure may include a plurality of battery cells each including an electrode assembly, an exterior material accommodating the electrode assembly therein, and an electrode lead connected to the electrode assembly and protruding to an outside of the exterior material, a busbar electrically connected to the electrode lead of each of the plurality of battery cells, a through hole formed through the busbar, a measurement part measuring electrical characteristics of at least one battery cell among the plurality of battery cells, and an insulation measuring member, one end of which is connected to the exterior material of one of the plurality of battery cells and an other end of which is electrically connected to the measurement part.

The exterior material may include aluminum.

The busbar may include a busbar plate, and the through hole may be located in a central portion of the busbar plate.

The busbar plate may further include a plurality of slit holes, and the through hole may be located between the plurality of slit holes.

A path connecting the one end and the other end of the insulation measuring member may pass through the through hole formed in the busbar.

A path connecting the one end and the through hole may be adjacent to an inner surface of the busbar, and a path connecting the through hole and the other end may be adjacent to an outer surface of the busbar.

The one end of the insulation measuring member may be connected to a lower surface portion of the exterior material.

The electrode lead may include a cathode lead and an anode lead, and the busbar may be electrically connected to the anode lead.

The battery assembly may further include a voltage measuring member, one end of which is connected to the busbar, and an other end of which is electrically connected to the measurement part, and the measurement part may be electrically connected to the voltage measuring member and the insulation measuring member.

The voltage measuring member and the insulation measuring member may be spaced apart from each other.

The measurement part may further include a determination module determining whether the battery assembly is abnormal based on measured electrical characteristics.

The measurement part may further include a notification module notifying a user of whether the battery assembly is abnormal.

A monitoring method of the battery assembly according to embodiments of the present disclosure may include a voltage application operation of applying a voltage to the exterior material of the at least one battery cell of the plurality of battery cells, a current measurement operation of measuring a current generated by the voltage applied during the voltage application operation, and an insulation resistance calculation operation of calculating an insulation resistance value of the exterior material based on the current measured during the current measurement operation.

The monitoring method may further include an abnormality determination operation of determining whether the battery assembly is abnormal by comparing the insulation resistance value calculated during the insulation resistance calculation operation with a reference resistance value.

The reference resistance value may be from 75 MΩ to 120 MΩ.

The monitoring method may further include a notification operation of notifying a user when it is determined during the abnormality determination operation that the battery assembly has an abnormality.

### BRIEF DESCRIPTION OF THE DRAWINGS

FIG. 1 is an exploded perspective view of a battery assembly according to an embodiment of the present disclosure.

FIG. 2 is an exploded perspective view of a battery cell according to an embodiment of the present disclosure.

FIG. 3 is a structural diagram illustrating a battery cell according to an embodiment of the present disclosure.

FIG. 4 is a structural diagram illustrating a busbar according to an embodiment of the present disclosure.

FIG. 5 is a view of a busbar according to an embodiment of the present disclosure when viewed from a first direction DR1.

FIG. 6 is a view of a configuration of a busbar, an insulation measuring member, and a voltage measuring member according to an embodiment of the present disclosure when viewed in the first direction DR1.

FIG. 7 is a diagram illustrating a coupling relationship between a busbar, an insulation measuring member, and a battery cell according to an embodiment of the present disclosure.

FIG. 8 is a view of a battery assembly according to an embodiment of the present disclosure when viewed from the first direction DR1.

FIG. 9 is an exploded perspective view of a battery assembly according to another embodiment of the present disclosure.

FIG. 10 is a flowchart illustrating processes for describing a method of monitoring a battery assembly according to an embodiment of the present disclosure.

FIG. 11 is a diagram illustrating a circuit configuration for measuring insulation resistance in association with a method of monitoring a battery assembly according to an embodiment of the present disclosure.

### DETAILED DESCRIPTION

Hereinafter, the present disclosure will be described in detail with reference to the accompanying drawing. However, those skilled in the art will appreciate that such embodiments described with reference to the accompanying drawing are provided to further understand the spirit of the present disclosure and do not limit subject matters to be protected as disclosed in the detailed description and appended claims. Furthermore, throughout the disclosure, unless otherwise particularly stated, the word “comprise”, “include”, “contain”, or “have” does not mean the exclusion of any other constituent element, but means further inclusion of other constituent elements, and elements, materials, or processes which are not further listed are not excluded.

Being equal or uniform in this specification may mean being equal or uniform to each other within an acceptable margin of error unless otherwise specified. For example, the fact that certain components or physical property measurement values are the same may include the meaning that the two objects to be compared are not only completely the same, but also the same within the error range. On the other hand, the fact that certain physical property measurement values are the same may mean that the difference in measurement values between objects is approximately less than 5%, specifically less than 3%, and more specifically less than 1%.

In this specification, that the angles formed by the two objects are perpendicular or parallel or parallel to each other may include not only being geometrically perpendicular or parallel, but also being within a slight error range.

The numerical range used in the present disclosure comprises all values within the range comprising the lower limit and the upper limit, increments logically derived in a form and spanning in a defined range, all double limited values, and all possible combinations of the upper limit and the lower limit in the numerical range defined in different forms.

Unless otherwise defined herein, “about” may be considered a value within 30%, 25%, 20%, 15%, 10%, or 5% of the stated value.

In the present specification, the term “face” may refer to that each object including at least one plane is positioned adjacently or non-adjacently with each plane kept parallel.

In this specification, “electrically connected” may mean, without limitation, any connection method by which a plurality of objects may be connected to each other so as to be in electrical communication with each other.

In this specification, a “first direction DR1,” a “second direction DR2,” and a “third direction DR3” may optionally refer to any one of directions constituting an orthogonal coordinate system with directions perpendicular to each other in a three-dimensional space.

A configuration defined herein as a “part,” a “portion,” or a “module” may mean a unit that processes at least one function or operation, and may be implemented in hardware or software, or a combination of hardware and software.

As used herein, the term “lithium secondary battery” may refer to a battery that generates electrical energy by oxidation and reduction reactions when lithium ions are inserted and extracted in and from a cathode and an anode.

As used herein, the term “battery cell” may refer to a basic unit of a lithium secondary battery capable of charging and discharging electrical energy.

Hereinafter, the present disclosure will be described in detail. This is, however, illustrative only and not intended to limit the disclosure to the specific embodiments illustratively described.

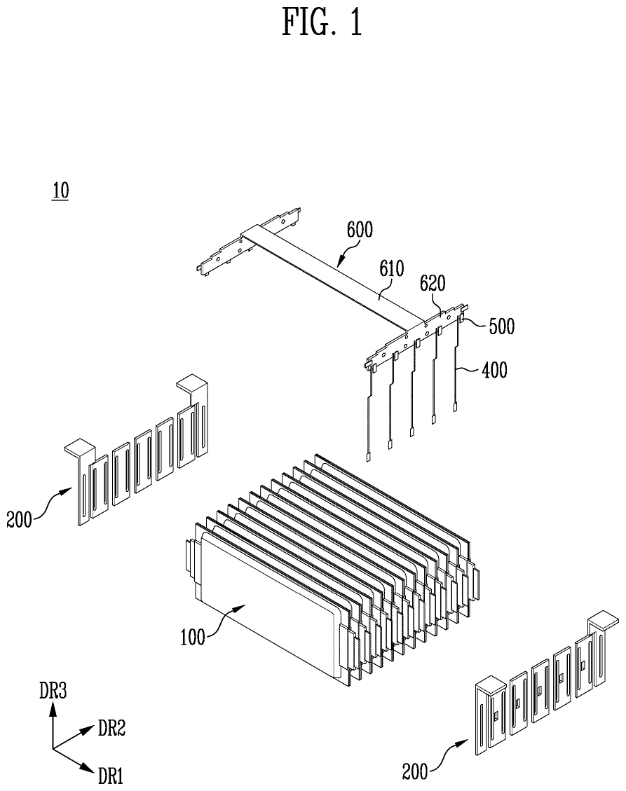

FIG. 1 is an exploded perspective view of a battery assembly 10 according to an embodiment of the present disclosure.

The battery assembly 10 according to an embodiment of the present disclosure may include: a plurality of battery cells 100 each including an electrode assembly 110, an exterior material 120 accommodating the electrode assembly 110 therein, and an electrode lead 130 connected to the electrode assembly 110 and protruding to the outside of the exterior material 120; a busbar 200 electrically connected to the electrode lead 130 of each of the plurality of battery cells 100; a through hole 240 formed through the busbar; a measurement part 300 for measuring electrical characteristics of at least one battery cell 100 among the plurality of battery cells 100; and an insulation measuring member 400 having one end connected to the exterior material 120 of one of the battery cells 100 and the other end electrically connected to the measurement part 300.

In an embodiment, each of the plurality of battery cells 100 may include a cathode and an anode.

According to an exemplary embodiment, the cathode may include a cathode current collector and a cathode active material applied to at least one surface of the cathode current collector. The cathode current collector may include a known conductive material to the extent that the cathode current collector does not cause a chemical reaction in a lithium secondary battery. The cathode current collector may include, for example, one of stainless steel, nickel (Ni), aluminum (Al), titanium (Ti), copper (Cu), and alloys thereof, and may be provided in various forms such as a film, a sheet, and foil. The cathode active material may include a material through which lithium ions are inserted and extracted. The cathode active material may be, for example, a lithium metal oxide.

According to an exemplary embodiment, the anode may include an anode current collector and an anode active material applied to at least one surface of the anode current collector. The anode current collector may include a known conductive material to the extent that the anode current collector does not cause a chemical reaction in the lithium secondary battery. The anode current collector may include, for example, one of stainless steel, nickel (Ni), aluminum (Al), titanium (Ti), copper (Cu), and alloys thereof, and may be provided in various forms such as a film, a sheet, and foil. The anode active material may include a material through which lithium ions may be inserted and extracted. The anode active material may include, for example, a carbon-based material such as crystalline carbon, amorphous carbon, a carbon composite, or carbon fiber, a lithium alloy, or one or a combination of silicon (Si) and tin (Sn).

According to an exemplary embodiment, each of the cathode and the anode may further include a binder and a conductive material for improving mechanical stability and electrical conductivity.

According to an exemplary embodiment, each battery cell 100 may further include a separator to prevent an electrical short-circuit between the cathode and the anode and to generate ion flow. The separator may include, for example, a porous polymer film or a porous nonwoven fabric.

Therefore, according to the embodiment, the electrode assembly 110 may have a structure in which an anode, a separator, and a cathode are stacked in a predetermined stacking direction. The anode, the separator, and the cathode may be stacked in a stacking, stack-folding or Z-stacking manner.

According to an exemplary embodiment, each of the battery cells 100 may include an electrolyte solution for immersing the electrode assembly 110 accommodated in the exterior material 120. The electrolyte solution may be a non-aqueous electrolyte solution. The electrolyte solution may include a lithium salt and an organic solvent, and may further include an additive if necessary.

According to another exemplary embodiment, each battery cell 100 may further include a solid electrolyte layer including an electrolyte in a solid form. Therefore, according to such an embodiment, the electrode assembly 110 may have a structure in which an anode, a solid electrolyte layer, and a cathode are stacked in the predetermined stacking direction.

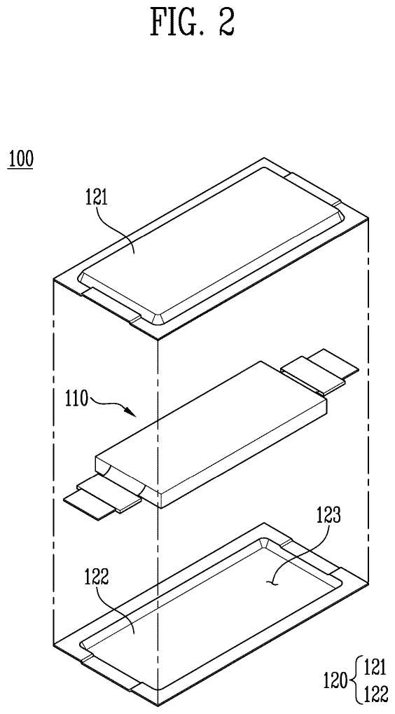

FIG. 2 is an exploded perspective view of the battery cell 100 according to an embodiment of the present disclosure.

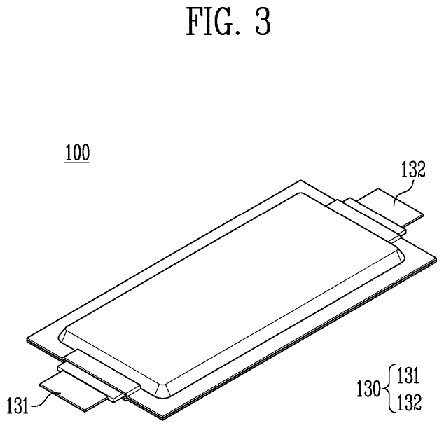

FIG. 3 is a structural diagram illustrating the battery cell 100 according to an embodiment of the present disclosure.

Referring to FIGS. 2 and 3, in an embodiment, each battery cell 100 may include the exterior material 120. The exterior material 120 may accommodate the electrode assembly 110 therein. More specifically, the electrode assembly 110 may be accommodated in the exterior material 120 by forming an accommodation space therein. The exterior material 120 may cover the electrode assembly 110 and protect the electrode assembly 110 by accommodating the electrode assembly 110 therein.

Each of the battery cells 100 may be classified into a pouch-type battery, a prismatic battery, a cylindrical battery, and the like according to the shape of the exterior material 120. In the present disclosure, a pouch-type secondary battery is shown as an example for convenience of description, but the present disclosure is not necessarily limited thereto.

In an embodiment, the exterior material 120 may include an upper cover 121 and a lower cover 122. The upper cover 121 and the lower cover 122 may be connected to form the accommodation space in the exterior material 120.

In an embodiment, the upper cover 121 and/or the lower cover 122 may include a cup portion 123 formed by recessing one surface. In one embodiment, the electrode assembly 110 may be located in the cup portion 123.

According to an exemplary embodiment, the upper cover 121 and/or the lower cover 122 may be integrally formed and then folded to form the accommodation space. In addition, the upper cover 121 and/or the lower cover 122 may be separately manufactured and sealed.

According to an exemplary embodiment, the exterior material 120 formed by folding or sealing as described above may form the accommodation space and four outer peripheral surfaces.

The four outer peripheral surfaces may include a pair of side surface portions 124 directly adjoining each of adjacent battery cells 100 in the predetermined stacking direction of the plurality of battery cells 100, and an upper surface portion 125 and a lower surface portion 126 facing each other between the pair of side surface portions 124. The stacking direction may refer to the second direction DR2 as shown in FIG. 1.

According to an exemplary embodiment, the pair of side surface portions 124 may be formed parallel to a plane including the first direction DR1 and the third direction DR3 as shown in FIG. 1. The upper surface portion 125 and the lower surface portion 126 may be formed parallel to a plane including the first direction DR1 and the second direction DR2 as shown in FIG. 1. The lower surface portion 126 may be adjacent to a support body 710 of a housing 700 according to an embodiment of the present disclosure to be described below, and the upper surface portion 125 may be adjacent to a cover body 720 of the housing 700 to be described below.

According to an exemplary embodiment, the exterior material 120 may further include a front surface portion 127 and a rear surface portion 128 which are formed at both ends of a region defined by the pair of side surface portions 124, the upper surface portion 125, and the lower surface portion 126, and the front surface portion 127 and the rear surface portion 128 face each other.

In one embodiment, the exterior material 120 may include aluminum. According to an exemplary embodiment, the exterior material 120 may refer to, but is not necessarily limited to, an aluminum laminate sheet.

Referring to FIGS. 1 to 3, in an embodiment, each battery cell 100 may include the electrode lead 130. The electrode lead 130 may be connected to the electrode assembly 110 and protrude to the outside of the exterior material 120. The electrode lead 130 may electrically connect the electrode assembly 110 isolated in the exterior material 120 to the outside. The electrode lead may include a conductor having high electrical conductivity and allowing transmission of electricity.

In an embodiment, the electrode lead 130 may include a cathode lead 131 connected to a cathode and an anode lead 132 connected to an anode.

According to an exemplary embodiment, the cathode lead 131 and the anode lead 132 may protrude outward from different side ends of the exterior material 120. The cathode lead 131 and the anode lead 132 may protrude in a direction different from the stacking direction. As shown in FIG. 1, for example, the cathode lead 131 may protrude in a direction opposite to the first direction DR1, and the anode lead 132 may protrude in the first direction DR1. On the other hand, the cathode lead 131 may protrude in the first direction DR1, and the anode lead 132 may protrude in the direction opposite to the first direction DR1.

In an embodiment, the plurality of battery cells 100 may be stacked in the predetermined stacking direction. As described above, based on FIG. 1, the stacking direction may be the second direction DR2. The plurality of battery cells 100 may be arranged to be parallel to each other. According to an exemplary embodiment, an auxiliary material such as a buffer material and a cooling plate may be inserted between the plurality of battery cells 100.

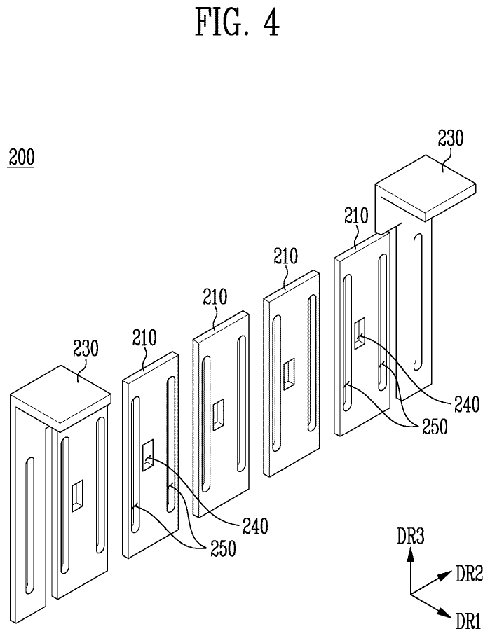

FIG. 4 is a structural diagram illustrating the busbar 200 according to an embodiment of the present disclosure.

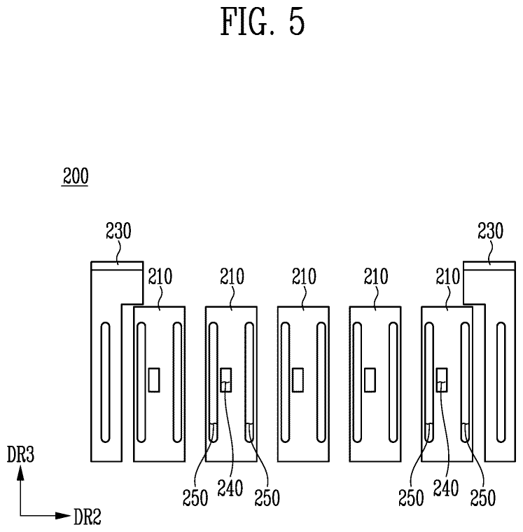

FIG. 5 is a view of the busbar 200 according to an embodiment of the present disclosure when viewed from the first direction DR1.

Referring to FIG. 1, in an embodiment, the battery assembly 10 may include the busbar 200 electrically connected to the electrode lead 130 of each of the plurality of battery cells 100. The busbar 200 may include a conductor which has high electrical conductivity and conducts electricity so that the busbar 200 may be electrically connected to the electrode lead 130. The busbar 200 may electrically connect the battery cell 100 to an external device. The busbar 200 may electrically connect one of the battery cells 100 included in the battery assembly 10 to another battery cell 100 included in the battery assembly 10.

In an embodiment of the present disclosure, the through hole 240 may be formed through the busbar 200, which will be described in more detail below.

Referring to FIGS. 4 and 5, in an embodiment, the busbar 200 may include a busbar plate 210, and the through hole 240 may be located in the center of the busbar plate 210.

In an embodiment, the busbar plate 210 may directly contact one or more of the plurality of battery cells 100 in the configuration of the busbar 200. To this end, a plurality of busbar plates may be provided. According to an exemplary embodiment, the busbar plate 210 may be manufactured as an individual component, or alternatively, the busbar plate 210 may be manufactured as an integral component.

In an embodiment, the number of busbar plates 210 may be the same as the number of battery cells 100.

In an embodiment, the number of busbar plates 210 may correspond to ½ of the number of battery cells 100. However, this is an example, and the number of busbar plates 210 may vary as necessary.

In an embodiment, the through hole 240 may penetrate the busbar plate 210 at a central portion of the busbar plate 240. The central portion of the busbar plate 240 may refer to a concept that encompasses both the center in a height direction and the center in a width direction of the busbar plate 210. As shown in FIGS. 4 and 5, for example, each of the busbar plates 210 may have a shape with a height in the height direction represented by the third direction DR3 and a width in the width direction represented by the second direction DR2. The through hole 240 may be formed over an intermediate portion of each of the height and width of the busbar plate 210.

In an embodiment, the through hole 240 may allow an insulation measuring member 400 to be described below to pass therethrough. The size of the through hole 240 is not particularly limited for the above purpose.

In an embodiment, the busbar plate 210 may further include a plurality of slit holes 250, and the through hole 240 may be located between the plurality of slit holes 250.

According to an exemplary embodiment, each of the slit holes 250 may be formed such that the electrode lead 130 may be fitted into the slit hole 250. Accordingly, each of the slit holes 250 may have a shape corresponding to that of the electrode lead 130. Each of the slit holes 250 may have a shape extending in the height direction of the busbar plate 210 as shown in FIGS. 4 and 5.

Two slit holes 250 may be provided at both ends of the busbar plate 210 in the width direction.

According to an exemplary embodiment, the through hole 240 may be located between an area where the slit holes 250 are spaced apart from each other in the width direction.

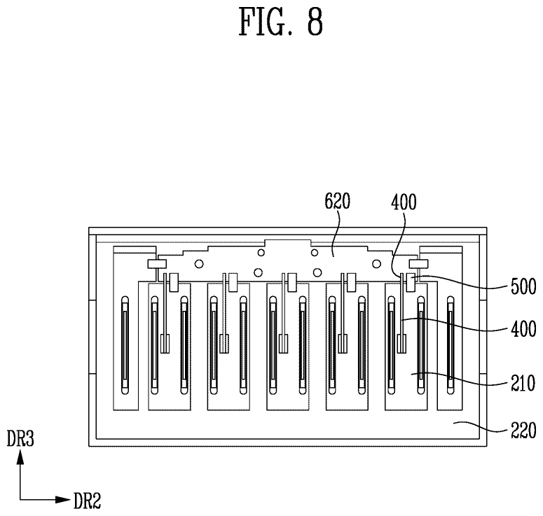

Referring to FIG. 8 to be described below, in an embodiment, the busbar 200 may further include a busbar frame 220.

In one embodiment, the plurality of busbar plates 210 may be coupled to the busbar frame 220. The busbar frame 220 may fix respective positions of the plurality of busbar plates 210 to be bonded. The bonding may be carried out, for example, by thermal fusion.

Referring to FIGS. 4 and 5, in an embodiment, the busbar 200 may further include busbar terminal portions 230.

In an embodiment, the busbar terminal portions 230 may be spaced apart in the stacking direction so that the plurality of busbar plates 210 may be arranged at regular intervals between the busbar terminal portions spaced apart from each other. As shown in FIGS. 4 and 5, for example, the busbar terminal portions 230 may be positioned at both ends in the second direction DR2.

In one embodiment, both the busbar terminal portion 230 and the busbar plate 210 may be coupled to the busbar frame 220.

In an embodiment, the battery assembly 10 may include the measurement part 300 configured to measure electrical characteristics of at least one battery cell 100 among the plurality of battery cells 100. The measurement part 300 will be described below.

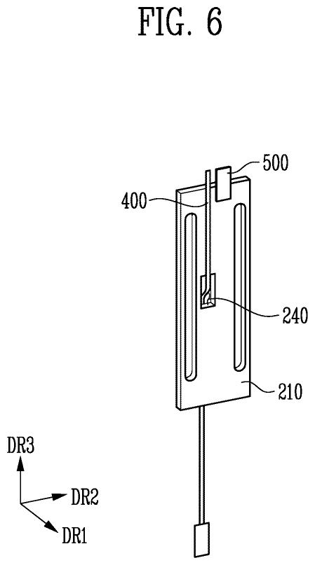

FIG. 6 is a view of a configuration of a busbar, an insulation measuring member, and a voltage measuring member according to an embodiment of the present disclosure when viewed in the first direction DR1.

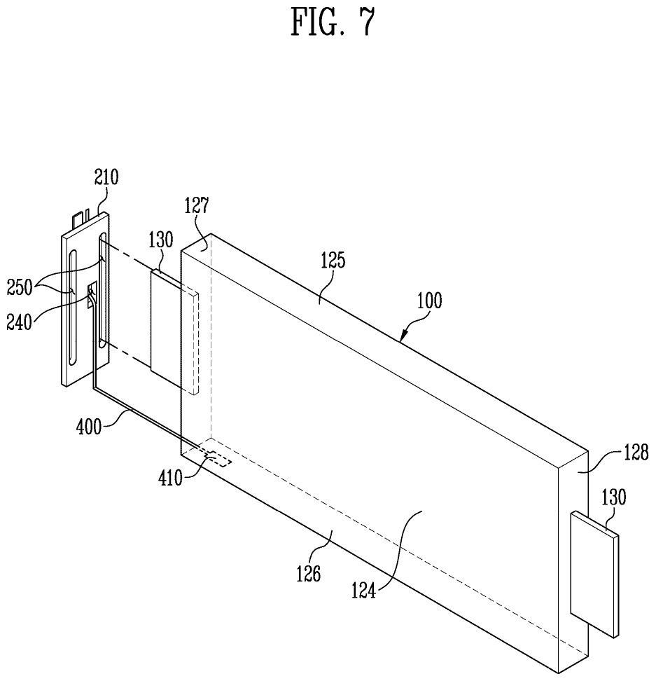

FIG. 7 is a diagram illustrating a coupling relationship between a busbar, an insulation measuring member, and a battery cell according to an embodiment of the present disclosure.

FIG. 8 is a view of the battery assembly 10 according to an embodiment of the present disclosure when viewed from the first direction DR1.

Referring to FIGS. 6 to 8, in an embodiment, the battery assembly 10 may include the insulation measuring member 400 having one end which is connected to the exterior material 120 of one of the plurality of battery cells 100, and the other end of which is coupled to the measurement part 300.

In an embodiment, the insulation measuring member 400 may measure whether the exterior material 120 deteriorates. To this end, one end of the insulation measuring member 400 is electrically connected to the exterior material 120 of one of the plurality of battery cells 100, and the other end is connected to the measurement part 300, so that the electrical characteristics of the exterior material 120 may be measured in real time.

Referring to FIG. 6, in an embodiment, a path connecting the one end and the other end of the insulation measuring member 400 may pass through the through hole 240 formed in the busbar 200.

According to an exemplary embodiment, the insulation measuring member 400 may be provided in the form of a line including a conductor. With this configuration, the electrical characteristics of the exterior material 120 may be transmitted to the measurement part 300. The insulation measuring member 400 having such a configuration may be provided between the measurement part 300 and the exterior material 120 so that the insulation measuring member 400 may pass through the through hole 240 formed in the busbar 200. That is, the busbar 200 of the battery assembly 10 according to an embodiment of the present disclosure includes the through hole 240, thereby providing a path through which the insulation measuring member 400 may reach the battery cell 100 at the shortest distance, and at the same time, further fixing the position of the insulation measuring member 300.

Referring to FIG. 6, in an embodiment, a path connecting the one end and the through hole 240 may be adjacent to an inner surface of the busbar 200, and a path connecting the through hole 240 and the other end may be adjacent to an outer surface of the busbar 200. The inner surface of the busbar 200 may refer to an outer peripheral surface adjacent to the exterior material 120 among the outer peripheral surfaces of the busbar 200, specifically of the busbar plate 210, and may refer to an outer peripheral surface facing the outside of the battery assembly 10 while the outer surface of the busbar 200 and the inner surface face each other. As shown in FIG. 1, for example, the inner surface and the outer surface may refer to a pair of outer peripheral surfaces spaced apart from and facing each other in the first direction DR1 among the outer peripheral surfaces of the busbar 200, specifically the busbar plate 210. The inner surface may refer to an outer peripheral surface adjacent to the exterior material 120 of the plurality of battery cells 100 in the pair of outer peripheral surfaces, and the outer surface may refer to an outer peripheral surface, of the pair of the outer surfaces, facing the outside of the battery assembly 10.

Referring to FIG. 7, in an embodiment, one end of the insulation measuring member 400 may be connected to the lower surface portion 126 of the exterior material 120. According to an exemplary embodiment, a ground portion 410 is formed at one end of the insulation measuring member 400, and the insulation measuring member 400 may be coupled to the exterior material 120 by coupling the ground portion 410 to the exterior material 120, specifically, the lower surface portion 126 of the exterior material 120.

The exterior material 120 of the battery cell 100 generally has an insulating structure. However, when the outer coating is corroded or degraded, a compound between lithium and the exterior material metal is formed and grown in the battery cell 100, and an electrode (or the electrode lead 130) and the exterior material 120 are electrically connected to each other to insulation breakdown. A short circuit may occur, which may lead to a fire and cause serious safety problems.

In particular, in the case of the pouch-type exterior material 120, structural deterioration or deformation of the lower surface portion 126 may occur frequently due to the shape of the shark fin. Whether or not the exterior material 120 is deteriorated may generally be evaluated by disassembling and inspecting the module. In the present disclosure, it is possible to evaluate and confirm whether the insulating property of the exterior material is maintained without separate disassembly, and whether such insulating property is maintained may be evaluated based on a resistance value calculated by applying a certain level of voltage to the exterior material 120.

In an embodiment, the insulation measuring member 400 may be electrically connected to the lower surface portion 126 of the exterior material 120 through the ground portion 410 formed at one end. The insulation measuring member 400 may be provided in the form of a line in which one end and the other end are electrically communicated. Therefore, the path extending from the one end toward the other end passes through the through hole 240 along the inner surface of the busbar 200 from the lower surface portion of the exterior material 120. After the path passes through the through hole 140, the other end is welded to a circuit member 600 to be described below along the outer surface of the busbar 200, and consequently, the other end may be connected to the measurement part 300.

In an embodiment, a plurality of insulation measuring members may be provided. For example, the number of insulation measuring members 400 may be the same as the number of busbar plates 210. As another example, the number of insulation measuring members 400 may correspond to ½ of the number of busbar plates 210. However, the present disclosure is not necessarily limited thereto, and the number of insulation measuring members 400 may vary as necessary.

With this configuration, the battery assembly 10 includes the insulation measuring member 400. Accordingly, the battery assembly 10 may be configured in a compact manner while maintaining structural stability.

In an embodiment, the electrode lead 130 includes the cathode lead 131 and the anode lead 132, and the busbar 200 may be electrically connected to the anode lead 132.

As described above, the cathode lead 131 and the anode lead 132 may protrude outward from different side ends of the exterior material 120. The busbar 200 electrically connected to the cathode lead 131 and the busbar 200 electrically connected to the anode lead 132 may be the same as or different from each other.

In an embodiment, the busbar 200 in one implementation of the present disclosure may be electrically connected to the anode lead 132. Accordingly, the insulation measuring member 400 in one implementation of the present disclosure may also be formed only at one end where the anode lead 132 is formed. Such dielectric breakdown is likely to be caused by the so-called anode connection where the anode (or the anode lead 132) and the exterior material 120 are electrically connected to each other. Therefore, in order to evaluate whether the exterior material 120 deteriorates in the anode direction as described above, the busbar 200 in one implementation of the present disclosure may be electrically connected to the anode lead 132. In addition, the cathode lead 131 may be electrically connected to a busbar of a conventional type, but is not necessarily limited thereto. For example, both the cathode lead 131 and the anode lead 132 may be electrically connected to the busbar 200 in one implementation of the present disclosure, and similarly, the insulation measuring members 400 may be formed in both the cathode lead 131 and the anode lead 132.

In an embodiment, the battery assembly 10 may further include: a voltage measuring member 500, one end of which is connected to the busbar 200, and the other end of which is electrically connected to the measurement part 300. The measurement part 300 may be electrically connected to the voltage measuring member 500 and the insulation measuring member 400.

In an embodiment, the voltage measuring member 500 may be welded to the busbar 200. More specifically, one end of the voltage measuring member 500 may be welded to the busbar plate 210. One end of the voltage measuring member 500 is welded to the busbar plate 210, and the other end thereof is welded to the circuit member 600 to be described below, so that the other end is connected to the measurement part 300.

Referring to FIGS. 6 to 8, in an embodiment, the voltage measuring member 500 and the insulation measuring member 400 may be spaced apart from each other. That is, the path connecting one end and the other end of the voltage measuring member 500 and the path connecting one end and the other end of the insulation measuring member 400 may be spaced apart from each other so as not to come into contact with each other.

As described above, even when the shape, form, or configuration of the busbar 200 electrically connected to the cathode lead 131 and the anode lead 132 varies, the busbar 200 which is electrically connected to the cathode lead 131 and the anode lead 132 may be coupled to the voltage measuring member 500. However, the present disclosure is not necessarily limited thereto, and the busbar 200 electrically connected to the cathode lead 131 may not be coupled to the voltage measuring member 500.

In an embodiment, the plurality of insulation measuring members 400 and the plurality of voltage measuring members 500 may be provided. For example, the number of voltage measuring members 500 may be the same as the number of busbar plates 210. However, the present disclosure is not necessarily limited thereto, and the number of voltage measuring members 500 may vary as necessary.

In an embodiment, the battery assembly 10 may further include the circuit member 600 including a first circuit member 610 extending in the same direction as the extending direction of each of the plurality of battery cells 100, and a second circuit member 620 extending from each end of the first circuit member 610 in the extending direction in a direction perpendicular to the extending direction of the first circuit member 610.

As shown in FIG. 1, for example, the first circuit member 610 may extend in the first direction DR1, and the second circuit member 620 may extend in the second direction DR2.

In an embodiment, the first circuit member 610 may cover one surface of at least some of the plurality of battery cells 100. In a specific embodiment, the first circuit member 610 may cover an upper surface of at least some of the plurality of battery cells 100.

In an embodiment, the second circuit member 620 may be electrically connected to the insulation measuring member 400 and/or the voltage measuring member 500. More specifically, the second circuit member 620 may be electrically connected to the insulation measuring member 400 and/or the voltage measuring member 500 as the second circuit member 620 is welded to the other end of the insulation measuring member 500. Therefore, the measurement part 300 may be electrically connected to the insulation measuring member 400 and/or the voltage measuring member 500 by the circuit member 600 including the first circuit member 610 and the second circuit member 620.

In an embodiment, the first circuit member 610 and the second circuit member 620 may be flexible printed circuit boards (FPCB). In an embodiment, the first circuit member 610 and the second circuit member 620 may be integrally formed.

In an embodiment, the battery assembly 10 may include the measurement part 300 configured to measure electrical characteristics of at least one battery cell 100 among the plurality of battery cells 100.

In an embodiment, the measurement part 300 may be electrically connected to the insulation measuring member 400 and the voltage measuring member 500. The configuration in which the measurement part 300 is electrically connected to the insulation measuring member 400 and/or the voltage measuring member 500 is the same as described with regard to the embodiment of the circuit member 600, and thus, the same description will be omitted below.

In an embodiment, the measurement part 300 may measure electrical characteristics of at least one battery cell 100 among the plurality of battery cells 100.

According to an exemplary embodiment, the electrical characteristic herein may refer to an insulation resistance characteristic of the exterior material 120 of the battery cell 100.

In an embodiment, the measurement part 300 may include a plurality of measurement terminals 310. Each of the plurality of measurement terminals 310 may be electrically connected to one of the other end of the insulation measuring member 400 and the other end of the voltage measuring member 500. In an embodiment, the measurement part 300 may include two measurement terminals 310, one of the measurement terminals 310 may be electrically connected to the other end of the insulation measuring member 400, and the other measurement terminal 310 may be electrically connected to the other end of the voltage measuring member 500.

In an embodiment, the measurement part 300 may include a measurement circuit and a measurement power source connected to the plurality of measurement terminals 310. In one embodiment, the measurement circuit may include one or more ammeters. In an exemplary embodiment, the measurement circuit may be electrically connected to the insulation measuring member 400 and the voltage measuring member 500 through the measurement terminal 310. That is, with the above configuration relationship, the measurement part 300, the insulation measuring member 400, the voltage measuring member 500, and the exterior material 120 may constitute one circuit.

In an embodiment, a voltage applied from the measurement power source may be transmitted to the insulation measuring member 400 through the measurement circuit and the measurement terminal 310, and may be applied to the exterior material 120 connected to one end of the insulation measuring member 300. The current generated therefrom may be measured by the measurement circuit, and an insulation resistance value of the exterior material 120 may be calculated based on the measured value.

In an embodiment, the configuration including the plurality of measurement terminals 310, the measurement circuit, and the measurement power of the measurement part 300 may be defined as a measurement module.

In an embodiment, the measurement part 300 may further include a determination module configured to determine whether the battery assembly 10 is abnormal based on the measured electrical characteristics.

According to an exemplary embodiment, the determination module may be electrically connected to the measurement module to determine whether the battery assembly 10 is abnormal based on electrical characteristics measured from the measurement module. The above method will be described below in more detail.

In an embodiment, the measurement part 300 may further include a notification module for notifying a user of whether the battery assembly 10 is abnormal.

According to an exemplary embodiment, the notification module may be electrically connected to the determination module or both the determination module and the measurement module. When the determination module determines that an abnormality has occurred in the battery assembly 10, a notification related to the occurrence of the abnormality may be delivered to the user. The above method will be described below in more detail.

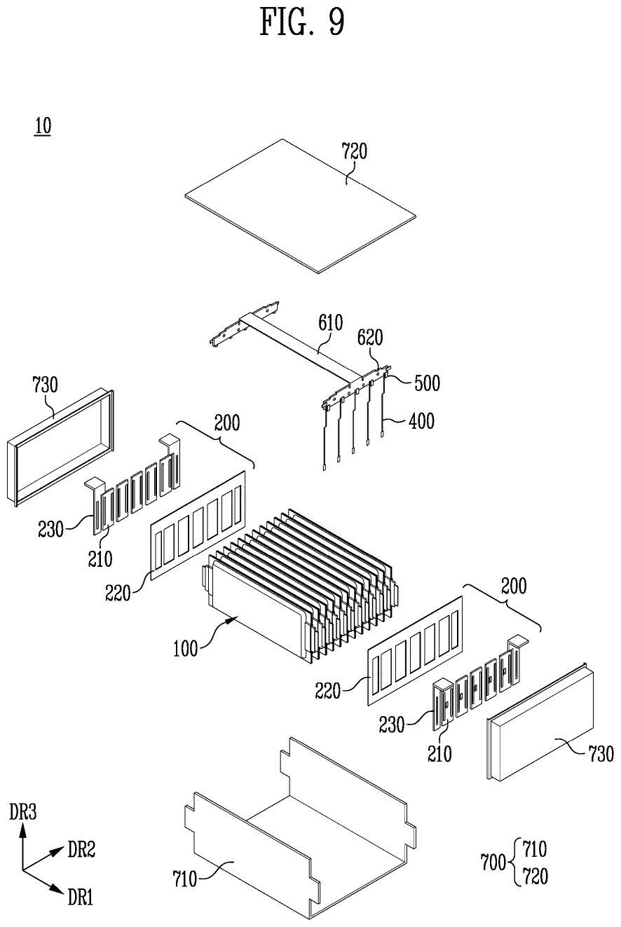

FIG. 9 is an exploded perspective view of the battery assembly 10 according to another embodiment of the present disclosure.

Referring to FIG. 9, in an embodiment, the battery assembly 10 may further include the housing 700 which covers the plurality of battery cells 100.

In an embodiment, the housing 700 may include the support body 710 which supports the plurality of battery cells 100 and the cover body 720 which is coupled to the support body 710 to form the housing 700.

In an embodiment, the housing 700 may further include an end cover 730 connected to the support body 710 and the cover body 720 to form one side of the inner space of the housing 700.

In an embodiment, the support body 710 may have a “U” shape so that an upper surface of the support body 710 may be coupled to the cover body 720 and front and rear surfaces thereof may be coupled to the end cover 730. As shown in FIG. 9, for example, the cover body 720 may be coupled to the support body 710 in the third direction DR3, and the end cover 730 may be coupled to the support body 710 in the first direction DR1. However, the shape of each component shown in FIG. 9 is arbitrary, and if necessary, the support body 710 may be provided so that the lower surface or the side surface of the support body 710 may be separable, allowing for coupling.

According to an exemplary embodiment, the cover body 720 may have a size corresponding to an opening of the support body 710, and may be coupled to the support body 710. The cover body 720 may be coupled to the support body 710 to form an inner surface of the inner space of the housing 700, so that the plurality of battery cells 100 may be arranged between the cover body 720 and the support body 710.

According to an exemplary embodiment, the support body 710 may include a conductor material or a non-conductor material. In an exemplary embodiment, the support body 710 may include a conductor material. Even when the support body 710 includes a conductor material as in the embodiment, the battery assembly 10 in one implementation of the present disclosure may measure and determine whether the exterior material 120 deteriorates in real time, so that the risk of short circuit occurrence may be prevented in advance.

In an embodiment, the housing 700 may have a hexahedral shape by the support body 710, the cover body 720, and the end cover 730, and the plurality of battery cells 100 may be arranged in the hexahedron shape for protection.

However, FIG. 9 merely shows one embodiment of the battery assembly according to the present disclosure, and the present disclosure may be configured in various aspects without departing from the matters defined herein.

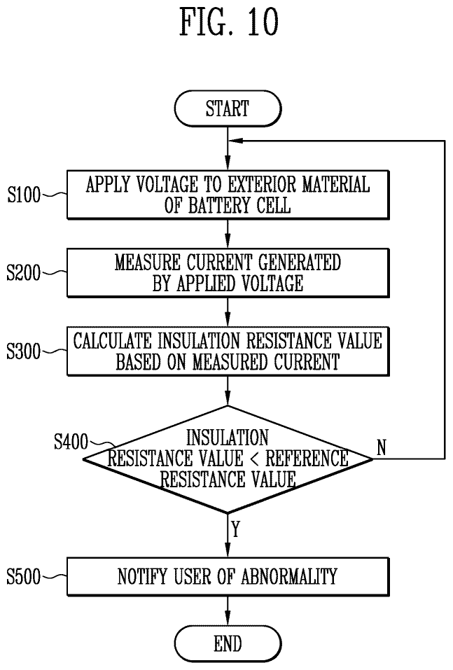

FIG. 10 is a flowchart illustrating processes for describing a method of monitoring a battery assembly according to an embodiment of the present disclosure.

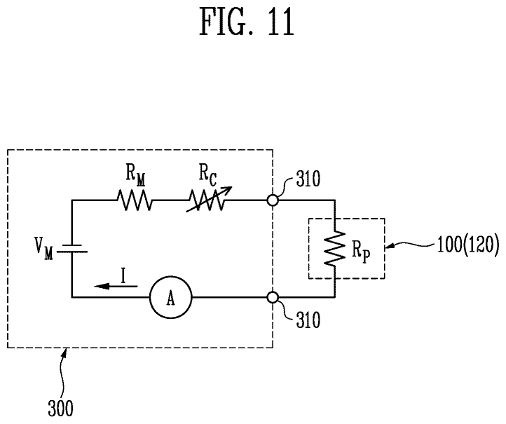

FIG. 11 is a diagram illustrating a circuit configuration for measuring insulation resistance in association with a method of monitoring the battery assembly 10 according to an embodiment of the present disclosure.

A method of monitoring the battery assembly 10 according to an embodiment of the present disclosure may include: a voltage application process at step S100 of applying a voltage to the exterior material 120 of at least one battery cell 100 among the plurality of battery cells 100; a current measurement process at step S200 of measuring a current generated by the voltage applied during the voltage application process at step S100; and an insulation resistance calculation process at step S300 of calculating an insulation resistance value of the exterior material 120 based on the current measured during the current measurement process at step S200.

In an embodiment, the voltage application process at step S100 may refer to a process of applying a voltage to the exterior material 120 of at least one battery cell 100 among the plurality of battery cells 100.

As described above, the measurement part 300, the insulation measuring member 400, the exterior material 120, and the voltage measuring member 500 may constitute one circuit. The voltage application process at step S100 may refer to a process of applying a voltage from the measurement part 300, specifically, the measurement power source of the measurement part 300 to the exterior material 120.

According to an exemplary embodiment, the voltage applied from the measurement power source may be 50 V.

In an embodiment, the current measurement process at step S200 may refer to a process of measuring the current generated by the voltage applied during the voltage application process at step S100.

A current may be generated in a circuit connecting the measurement part 300, the insulation measuring member 400, the exterior material 120, and the voltage measuring member 500 by the voltage applied during the voltage application process at step S100. The measurement circuit constituting the measurement part 300 has an internal resistance R_{M}, and an adjustment resistance R_{C} for zero-point adjustment may be separately present. Therefore, when a current is measured in a path from the measurement part 300 to the exterior material 120 via the insulation measuring member 400 and then back to the measurement part 300 via the voltage measuring member 500, an insulation resistance (R_{P}) value of the exterior material 120 may be measured. The ammeter may be configured to measure the current on the path from the exterior material to the measurement part 300.

In an embodiment, the insulation resistance calculation process at step S300 may include calculating the insulation resistance value of the exterior material 120 based on the current measured during the current measurement process at step S200.

FIG. 11 is a diagram illustrating a circuit configuration for measuring the insulation resistance R_{P} value of the exterior material 120 of the battery assembly 10 according to an embodiment of the present disclosure.

As described above, a voltage V_{M} from the measurement power source of the measurement part 300 may be applied to the exterior material 120 through the insulation measuring member 400 connected to the measurement terminal 310 via the measurement circuit. A current I measured in the ammeter may be determined by the internal resistance R_{M}, the adjustment resistance R_{C}, the insulation resistance R_{P}, and the voltage V_{M}. With this relationship, the insulation resistance R_{P} may satisfy a relationship defined by the following relational expression:

$${R}_{P} = \frac{{V}_{M}}{I} - {R}_{M} - {R}_{C} \qquad [ Relational Formula 1 ]$$

The voltage V_{M}, the internal resistance R_{M}, and the adjustment resistance R_{C} are values which are set beforehand or measured. The insulation resistance calculation process at step S300 may include calculating the insulation resistance R_{P} of the exterior material 120 based on the current value measured during the current measurement process at step S200.

In an embodiment, the voltage application process at step S100, the current measurement process at step S200, and the insulation resistance calculation process at step S300 may be performed by the measurement part 300, and specifically, may be performed by a measurement module of the measurement part 300.

In an embodiment, the method of monitoring the battery assembly 10 may further include an abnormality determination process at step S400 of determining whether the battery assembly 10 is abnormal by comparing the insulation resistance value calculated in the insulation resistance calculation process at step S300 with a reference resistance value.

A process of calculating the insulation resistance value in the insulation resistance calculation process at step S300 is as described above. In the abnormality determination process at step S400, the abnormality of the battery assembly 10 may be determined by comparing the insulation resistance value calculated during the insulation resistance calculation process at step S300 with a predetermined reference resistance value.

In an embodiment, the abnormality determination process at step S400 may include determining that an abnormality has occurred in the battery assembly 10 when the insulation resistance value is lower than the reference resistance value. As described above, when deterioration such as tearing or peeling occurs in the exterior material 120, insulation breakdown of the exterior material 120 may be caused. The insulation resistance R_{P} of the exterior material 120 may decrease, and it may be determined that deterioration has occurred in the exterior material 120 when it is measured that the insulating resistance R_{P} has decreased to a predetermined reference value or less. That is, determining whether the battery assembly 10 is abnormal during the abnormality determination process at step S400 may mean determining whether deterioration has occurred in the exterior material 120 based on whether the measured insulation resistance R_{P} value of the exterior material 120 is equal to or less than the reference resistance value.

In one embodiment, the reference resistance value may be between 75 MΩ and 120 MΩ. Specifically, the reference resistance value may be 90 MΩ to 105 MΩ, and more specifically, the reference resistance value may be 100 MΩ.

In an embodiment, the battery assembly 10 further includes the voltage measuring member 500 configured to measure a voltage of one battery cell 100 among the plurality of battery cells 100, and the abnormality determination process at step S400 may include determining whether the battery assembly 10 is abnormal based on a voltage value of the one battery cell 100 measured from the voltage measuring member 500 and the insulation resistance value calculated during the insulation resistance calculation process at step S300.

One end of the voltage measuring member 500 is connected to the busbar 200, and the other end thereof is connected to the measurement part 300 as described above. With the configuration of the voltage measuring member 500, the voltage of one of the battery cells 100 may be measured in real time. When the measured voltage value of one of the battery cells 100 deviates from the reference value, it may be determined that an abnormal situation has occurred in the battery assembly 10.

In an embodiment, in the abnormality determination process at step S400, the abnormality of the battery assembly 10 may be determined by comparing the insulation resistance value with a reference resistance value, and/or by comparing the voltage value of one of the battery cells 100 with a reference value. That is, the monitoring method of the battery assembly 10 in one implementation of the present disclosure may include monitoring the voltage of the battery cell 100 in the assembly 10 and determining whether the exterior material 120 of the battery cell 100 deteriorates in real time, and may enable to more quickly and accurately determine possible abnormal conditions in the battery assembly 10.

In an embodiment, the abnormality determination process at step S400 may be performed by the measurement part 300, and specifically, may be performed by a determination module of the measurement part 300.

In an embodiment, the method of monitoring the battery assembly 10 may further include a notification process at step S500 of notifying the user when it is determined during the abnormality determining process at step S400 that the battery assembly 10 has an abnormality.

In an embodiment, the notification may be issued by means of a notification means provided in a device which uses the battery assembly 10 as a power source. For example, when the notification means provides a notification visually, the notification means may perform the notification by emitting light, generating heat, or displaying a notification-related phrase or display to the user. When the notification means provides a notification by an audible means, the notification means may perform the notification by outputting a sound including a specific phrase and/or a signal sound. The above notification may be performed using both the visual means and the audible means, and if necessary, the notification may be performed by means other than those described above.

In one embodiment, the notification may be performed via a portable device of the user of the device powered by the battery assembly 10 in conjunction with the portable device. For example, the notification may be issued by sending a text message or a notification phone to the portable device, or by utilizing an application separately installed on the portable device.

In an embodiment, the notification process at step S500 may be performed by the measurement part 300, and specifically, may be performed by a notification module of the measurement part 300.

A method of monitoring the battery assembly 10 in one implementation of the present disclosure may be performed on at least one battery cell 100 among the plurality of battery cells 100 in the battery assembly 10, may be simultaneously performed on at least two or more battery cells 100 among the plurality of battery cells 100, and may be simultaneously performed for all of the plurality of battery cell 100. When it is determined that an abnormality has occurred in at least one of the battery cells 100 monitored by the monitoring method, the notification may be provided to the user through the notification process at step S500.

The battery assembly 10 in one implementation of the present disclosure may be included in one configuration of a battery pack.

The battery assembly 10 according to an embodiment of the present disclosure may be preferably used as a power source for a small or medium-sized device. Examples of the small device include a mobile phone, a notebook computer, a camera, and the like, and examples of the medium-sized device include an electric vehicle, a hybrid electric vehicle, a plug-in hybrid electric vehicle, and a power storage system, but are not limited thereto.

According to an aspect of the present disclosure, a battery assembly with improved safety may be provided.

According to another aspect of the present disclosure, a method of monitoring a battery assembly that can quickly and accurately determine whether each battery cell in the battery assembly is degraded may be provided.

Meanwhile, the present disclosure may be widely applied in the fields of electric vehicles, battery charging stations, energy storage systems (ESS), and other green technologies such as photovoltaics and wind power using batteries. In addition, the present disclosure may be used in eco-friendly mobility, including electric vehicles and hybrid vehicles, to prevent climate change by suppressing air pollution and greenhouse fluid emissions.

The present disclosure may be modified and implemented in various forms, and its scope is not limited to the above-described embodiments. The content described above is merely an example of applying the principles of the present disclosure, and other features may be further included without departing from the scope of embodiments according to the present disclosure.

What is claimed is:

1. A battery assembly comprising:
a plurality of battery cells each including an electrode assembly, an exterior material accommodating the electrode assembly therein, and an electrode lead connected to the electrode assembly and protruding to an outside of the exterior material;
a busbar electrically connected to the electrode lead of each of the plurality of battery cells;
a through hole formed through the busbar;
a measurement part measuring electrical characteristics of at least one battery cell among the plurality of battery cells; and
an insulation measuring member, one end of which is connected to the exterior material of one of the plurality of battery cells and an other end of which is electrically connected to the measurement part.

2. The battery assembly according to claim 1, wherein the exterior material comprises aluminum.

3. The battery assembly according to claim 1, wherein the busbar comprises a busbar plate, and
wherein the through hole is located in a central portion of the busbar plate.

4. The battery assembly according to claim 3, wherein the busbar plate further comprises a plurality of slit holes, and
wherein the through hole is located between the plurality of slit holes.

5. The battery assembly according to claim 1, wherein a path connecting the one end and the other end of the insulation measuring member passes through the through hole formed in the busbar.

6. The battery assembly according to claim 5, wherein a path connecting the one end and the through hole is adjacent to an inner surface of the busbar, and a path connecting the through hole and the other end is adjacent to an outer surface of the busbar.

7. The battery assembly according to claim 1, wherein the one end of the insulation measuring member is connected to a lower surface portion of the exterior material.

8. The battery assembly according to claim 1, wherein the electrode lead comprises a cathode lead and an anode lead, and
wherein the busbar is electrically connected to the anode lead.

9. The battery assembly according to claim 1, further comprising a voltage measuring member, one end of which is connected to the busbar, and an other end of which is electrically connected to the measurement part,
wherein the measurement part is electrically connected to the voltage measuring member and the insulation measuring member.

10. The battery assembly according to claim 9, wherein the voltage measuring member and the insulation measuring member are spaced apart from each other.

11. The battery assembly according to claim 1, wherein the measurement part further includes a determination module determining whether the battery assembly is abnormal based on measured electrical characteristics.

12. The battery assembly according to claim 1, wherein the measurement part further includes a notification module notifying a user of whether the battery assembly is abnormal.

13. A monitoring method of the battery assembly according to claim 1, the monitoring method comprising:
a voltage application operation of applying a voltage to the exterior material of the at least one battery cell of the plurality of battery cells;
a current measurement operation of measuring a current generated by the voltage applied during the voltage application operation; and
an insulation resistance calculation operation of calculating an insulation resistance value of the exterior material based on the current measured during the current measurement operation.

14. The monitoring method according to claim 13, further comprising an abnormality determination operation of determining whether the battery assembly is abnormal by comparing the insulation resistance value calculated during the insulation resistance calculation operation with a reference resistance value.

15. The monitoring method according to claim 14, wherein the reference resistance value is from 75 MΩ to 120 MΩ.

16. The monitoring method according to claim 14, further comprising a notification operation of notifying a user when it is determined during the abnormality determination operation that the battery assembly has an abnormality.
